(19) United States
(12) Patent Application Publication
(10) Pub. No.: US 2019/0295864 A1
(43) Pub. Date: Sep. 26, 2019

(54) SUBSTRATE PROCESSING APPARATUS

(71) Applicant: Tokyo Electron Limited, Tokyo (JP)

(72) Inventors: Masashi Itonaga, Kumamoto (JP); Koji Ushimaru, Kumamoto (JP)

(21) Appl. No.: 16/360,357

(22) Filed: Mar. 21, 2019

(30) Foreign Application Priority Data
Mar. 22, 2018 (JP) 2018-054657

(51) Int. Cl. H01L 21/67; H01J 37/32

(52) U.S. Cl. CPC H01L 21/67017; H01L 21/67288; H01J 37/32449; H01L 21/67253

(57) ABSTRACT

A substrate processing apparatus includes: placing table on which a substrate to be processed is placed; suction mechanism including a pipe configured to apply a suction force to a rear surface of the substrate through one or a plurality of hole portions formed in the placing table to hold the substrate; and fluid supply source configured to discharge a fluid to one or a plurality of discharge portions formed in the placing table outward of the hole portions in the placing table and to form a horizontal airflow toward an outside of the substrate on a rear surface of the substrate.

### CROSS-REFERENCE TO RELATED APPLICATIONS

This application is based on and claims priority from Japanese Patent Application No. 2018-054657, filed on Mar. 22, 2018, with the Japan Patent Office, the disclosure of which is incorporated herein in its entirety by reference.

### TECHNICAL FIELD

The present disclosure relates to a substrate processing apparatus.

### BACKGROUND

Japanese Patent Laid-open Publication No. 2013-004804 discloses a substrate processing apparatus that supplies hexamethyldisilazane (HMDS) gas to the surface of a substrate placed in a processing container to make the substrate hydrophobic.

### SUMMARY

A substrate processing apparatus according to one aspect of the present disclosure includes: placing table on which a substrate to be processed is placed; suction mechanism including a pipe configured to apply a suction force to a rear surface of the substrate through one or a plurality of hole portions formed in the placing table to hold the substrate; and fluid supply source configured to discharge a fluid to one or a plurality of discharge portions formed in the placing table outward of the hole portions in the placing table and to form a horizontal airflow toward an outside of the substrate on a rear surface of the substrate.

In the substrate processing apparatus according to the present disclosure, the fluid supply source discharges the fluid to the discharge portions formed outward of the hole portions in the placing table and forms the horizontal airflow toward the outside of the substrate. Through the formation of the airflow, a negative pressure is generated by the Bernoulli effect in a region close to the center of the rear surface of the substrate (a region closer to the center than a region corresponding to a discharge port of the discharge portions), and a force is applied to suck the substrate toward the placing table. Both the suction force by the negative pressure caused by the Bernoulli effect and the suction force of the suction mechanism are applied to the substrate. Thus, it is possible to appropriately hold the substrate on the placing table and it is possible to prevent the warpage of the substrate. In addition, by the Bernoulli effect caused by the horizontal airflow, a positive pressure is generated in an outer region of the rear surface of the substrate (the region outward of the region corresponding to the discharge port of the discharge portions). In this way, since a force is also applied to a direction different from the suction force of the suction mechanism by the fluid supply source, by adjusting the discharge flow rate of the fluid in the fluid supply source in consideration of the suction force of the suction mechanism, it is possible to adjust the posture of the substrate on the placing table (e.g., hold the substrate in a state where the substrate and the placing table are spaced apart from each other by a constant distance) and to increase the degree of freedom of a substrate processing. In addition, since it is difficult for a gap pin on the placing table to come into contact with the substrate when the substrate is spaced apart from the placing table by the positive pressure of the Bernoulli effect, it is possible to appropriately prevent, for example, the occurrence of scratches on the rear surface of the substrate and the generation of particles caused when a metal film on the rear surface peels off.

In the substrate processing apparatus, a plurality of discharge portions may be provided, and the plurality of discharge portions may be formed in a concentric shape with respect to the substrate. Therefore, the regions on the rear surface side of the wafer W corresponding to the plurality of discharge portions may be at the same position (having the same distance from the center of the substrate), and the substrate may be held more stably.

In the substrate processing apparatus, the discharge portions may extend obliquely with respect to a placing surface of the placing table on which the substrate is placed. Therefore, the horizontal flow may be easily formed on the rear surface side of the substrate.

In the substrate processing apparatus, an inclination angle of the discharge portions with respect to the placing surface may be 60 degrees or less or may be 30 degrees or less. Therefore, the horizontal flow may be easily formed on the rear surface side of the substrate.

The substrate processing apparatus may further include a processing gas supply source configured to supply a processing gas to a processing container that accommodates the substrate, and the placing table may be a hot plate configured to heat the substrate. In a configuration in which the substrate is heated by the placing table and the processing gas is supplied to the substrate as described above, for example, the processing gas (e.g., the processing gas or an unnecessary substance generated during a processing) may circulate to the rear surface side of the substrate and react with the substrate. In this respect, in the substrate processing apparatus according to the present disclosure, since the fluid is discharged toward the outside of the substrate from the discharge portions outward of the hole portions, it is possible to prevent, for example, the processing gas from circulating to the rear surface side of the substrate by the fluid.

In the substrate processing apparatus, a flow velocity of the processing gas supplied by the processing gas supply source toward an outside of a surface of the substrate may be lower than a flow velocity of the airflow formed by the fluid supply source toward an outside of the rear surface of the substrate. Therefore, it is possible to appropriately hold the substrate on the placing table by the Bernoulli effect.

A discharge flow rate of the fluid supply source may be higher than a suction flow rate of the suction mechanism. It is conceivable that, for example, the above-described processing gas is guided to the rear surface side of the substrate by the suction of the suction mechanism. In this respect, by setting the discharge flow rate of the fluid discharged toward the outside of the substrate to be higher than the suction flow rate of the suction mechanism, it is possible to effectively prevent, for example, the processing gas from circulating to the rear surface side of the substrate by the suction of the suction mechanism.

The substrate processing apparatus may further include a controller configured to control the suction mechanism to start suction, and control the fluid supply source to start discharge of the fluid after suction by the suction mechanism is started. For example, when the discharge of the fluid by the fluid supply source is performed prior to the suction by the suction mechanism, it is conceivable that the substrate excessively floats due to the positive pressure of the Bernoulli effect and the warpage of the substrate may not be sufficiently prevented. In this respect, when the discharge of the fluid by the fluid supply source is started to generate the positive pressure after the substrate is held toward the placing table by the suction mechanism, it is possible to adjust the amount of floating of the substrate by adjusting the positive pressure of the Bernoulli effect after the substrate is reliably held on the placing table (i.e., after the warpage of the substrate is appropriately prevented).

The controller may further be configured to control the processing gas supply unit to start supply of the processing gas after the discharge of the fluid by the fluid supply source is started. Therefore, it is possible to more effectively prevent, for example, the processing gas from circulating to the rear surface of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a perspective view illustrating a schematic configuration of a substrate processing system.

FIG. 2 is a cross-sectional view taken along line II-II in FIG. 1.

FIG. 3 is a cross-sectional view taken along line in FIG. 2.

FIG. 4 is a schematic diagram illustrating a schematic configuration of a hydrophobic processing unit.

FIG. 5 is a diagram for explaining the Bernoulli effect generated by rear surface purge.

FIG. 6 is a diagram illustrating a hardware configuration of a controller.

FIG. 7 is a flowchart of a hydrophobic processing procedure.

FIG. 8 is a diagram for explaining the effect of a hydrophobic processing unit.

### DETAILED DESCRIPTION

In the following detailed description, reference is made to the accompanying drawings, which form a part of the present disclosure. The illustrative embodiments described in the detailed description, drawing, and claims are not meant to be in any way limiting. Other embodiments may be utilized, and other changes may be made without departing from the spirit or the scope of the subject matter presented here.

Hereinafter, embodiments will be described in detail with reference to the accompanying drawings. In the description, the same reference numerals will be attached to the same elements or elements having the same function, and a redundant description thereof will be omitted.

<Substrate Processing System>

The substrate processing system 1 is a system that performs, with respect to a substrate, formation of a photosensitive coating film, exposure of the photosensitive coating film, and developing of the photosensitive coating film. The substrate as a processing object is, for example, a semiconductor wafer W. The photosensitive coating film is, for example, a resist film. The substrate processing system 1 includes a coating and developing apparatus 2 and an exposure apparatus 3. The exposure apparatus 3 performs an exposure processing of the resist film (photosensitive coating film) formed on the wafer W (substrate). Specifically, an exposure object portion of the resist film is irradiated with an energy beam by a method such as, for example, liquid immersion exposure. The coating and developing apparatus 2 performs a processing of forming the resist film on a surface of the wafer W (substrate) before the exposure processing by the exposure apparatus 3, and performs a developing processing of the resist film after the exposure processing.

[Substrate Processing Apparatus]

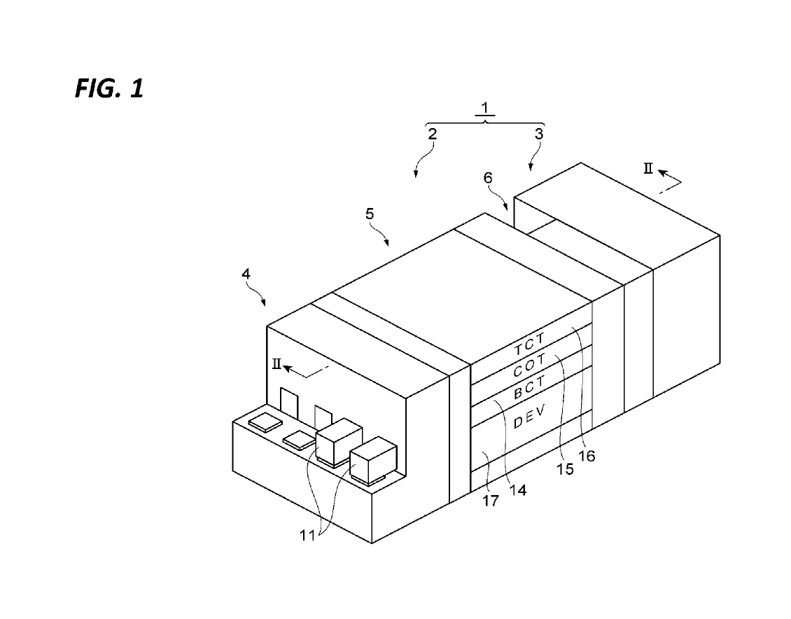

Hereinafter, a configuration of the coating and developing apparatus 2 will be described as an example of a substrate processing apparatus. As illustrated in FIGS. 1 to 3, the coating and developing apparatus 2 includes a carrier block 4, a processing block 5, an interface block 6, and a controller 100 (control unit).

The carrier block 4 performs the carry-in of the wafer W into the coating and developing apparatus 2 and the carry-out of the wafer W from the coating and developing apparatus 2. For example, the carrier block 4 is capable of supporting a plurality of carriers 11 for the wafer W, and incorporates therein a delivery arm A1. The carrier 11 accommodates, for example, a plurality of circular wafers W. The delivery arm A1 takes out the wafer W from the carrier 11 to deliver the wafer W to the processing block 5, and receives the wafer W from the processing block 5 to return the wafer W into the carrier 11.

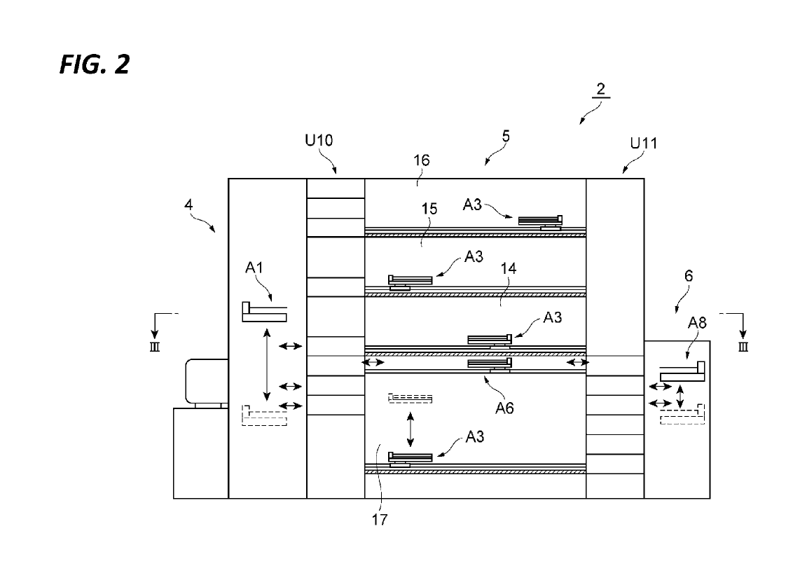

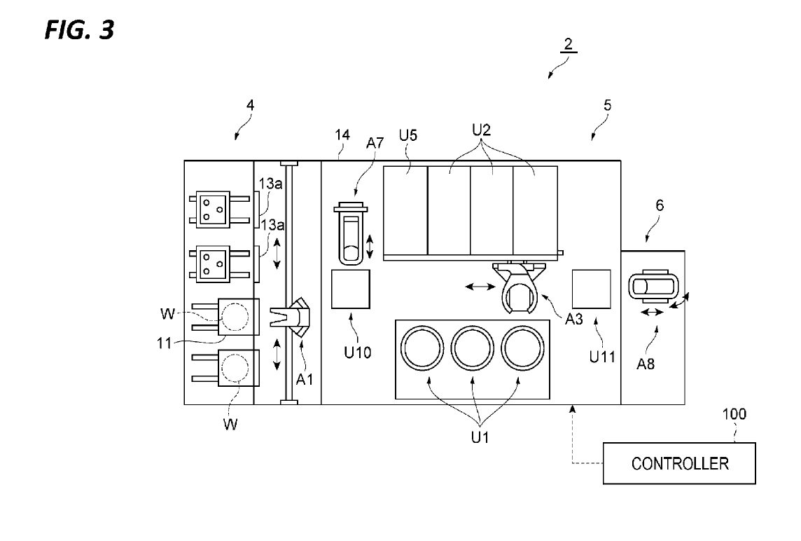

The processing block 5 includes a plurality of processing modules 14, 15, 16 and 17. As illustrated in FIGS. 2 and 3, the processing modules 14, 15, 16 and 17 incorporate a plurality of liquid processing units U1, a plurality of thermal processing units U2, and a transfer arm A3 that transfers the wafer W to these units. The processing module 17 further incorporates a direct transfer arm A6 that transfers the wafer W without passing through the liquid processing unit U1 and the thermal processing unit U2. The liquid processing unit U1 supplies a processing liquid to a surface of the wafer W. The thermal processing unit U2 incorporates therein, for example, a hot plate and a cooling plate, and performs a thermal processing by heating the wafer W with the hot plate and cooling the heated wafer W with the cooling plate.

The processing module 14 forms a lower layer film (e.g., an antireflection film) on the surface of the wafer W by the liquid processing unit U1 and the thermal processing unit U2. The liquid processing unit U1 of the processing module 14 coats a processing liquid for the formation of the lower layer film on the wafer W. The thermal processing unit U2 of the processing module 14 performs various thermal processings accompanying the formation of the lower layer film. As a specific example of the thermal processing performed in the thermal processing unit U2 of the processing module 14, a heating processing for curing the lower layer film may be mentioned. The processing module 14 further includes a hydrophobic processing unit U5. The hydrophobic processing unit U5 is configured to perform, for example, on the surface of the wafer W on which the lower layer film has been formed, a hydrophobic processing for enhancing adherence when coating various films. Details of the hydrophobic processing unit U5 will be described later.

The processing module 15 forms a resist film on the lower layer film by the liquid processing unit U1 and the thermal processing unit U2. The liquid processing unit U1 of the processing module 15 coats a processing liquid for the formation of the resist film on the lower layer film. The thermal processing unit U2 of the processing module 15 performs various thermal processings accompanying the formation of the resist film.

The processing module 16 forms an upper layer film on the resist film by the liquid processing unit U1 and the thermal processing unit U2. The liquid processing unit U1 of the processing module 16 coats a liquid for the formation of the upper layer film on the resist film. The thermal processing unit U2 of the processing module 16 performs various thermal processings accompanying the formation of the upper layer film.

The processing module 17 performs a developing processing of the resist film after exposure by the liquid processing unit U1 and the thermal processing unit U2. The liquid processing unit U1 of the processing module 17 performs a developing processing of the resist film by coating a developing liquid on the surface of the completely exposed wafer W and then rinsing the developing liquid with a rinsing liquid. The thermal processing unit U2 of the processing module 17 performs various thermal processings accompanying the developing processing. As a specific example of the thermal processing, a heating processing before the developing processing (post exposure bake (PEB)) or a heating processing after the developing processing (post bake (PB)) may be mentioned.

A shelf unit U10 is provided on the carrier block 4 side in the processing block 5. The shelf unit U10 is partitioned into a plurality of cells aligned in the vertical direction. An elevating arm A7 is provided in the vicinity of the shelf unit U10. The elevating arm A7 raises and lowers the wafer W between the cells of the shelf unit U10.

A shelf unit U11 is provided on the interface block 6 side in the processing block 5. The shelf unit U11 is partitioned into a plurality of cells aligned in the vertical direction.

The interface block 6 performs delivery of the wafer W to and from the exposure apparatus 3. For example, the interface block 6 incorporates therein a delivery arm A8, and is connected to the exposure apparatus 3. The delivery arm A8 delivers the wafer W placed on the shelf unit U11 to the exposure apparatus 3, and receives the wafer W from the exposure apparatus 3 to return the wafer W to the shelf unit U11.

The controller 100 controls the coating and developing apparatus 2 to execute a coating and developing processing in the following procedure, for example. First, the controller 100 controls the delivery arm A1 so as to transfer the wafer W in the carrier 11 to the shelf unit U10, and controls the elevating arm A7 so as to place the wafer W in the cell for the processing module 14.

Subsequently, the controller 100 controls the transfer arm A3 so as to transfer the wafer W of the shelf unit U10 to the liquid processing unit U1 and the thermal processing unit U2 in the processing module 14, and controls the liquid processing unit U1, the thermal processing unit U2, and the hydrophobic processing unit U5 so as to form a lower layer film on the surface of the wafer W. Thereafter, the controller 100 controls the transfer arm A3 so as to return the wafer W on which the lower layer film has been formed to the shelf unit U10, and controls the elevating arm A7 so as to place the wafer W in the cell for the processing module 15.

Subsequently, the controller 100 controls the transfer arm A3 so as to transfer the wafer W of the shelf unit U10 to the liquid processing unit U1 and the thermal processing unit U2 in the processing module 15, and controls the liquid processing unit U1 and the thermal processing unit U2 so as to form a resist film on the lower layer film of the wafer W. Thereafter, the controller 100 controls the transfer arm A3 so as to return the wafer W to the shelf unit U10, and controls the elevating arm A7 so as to place the wafer W in the cell for the processing module 16.

Subsequently, the controller 100 controls the transfer arm A3 so as to transfer the wafer W of the shelf unit U10 to each unit in the processing module 16, and controls the liquid processing unit U1 and the thermal processing unit U2 so as to form an upper layer film on the resist film of the wafer W. Thereafter, the controller 100 controls the transfer arm A3 so as to return the wafer W to the shelf unit U10, and controls the elevating arm A7 so as to place the wafer W in the cell for the processing module 17.

Subsequently, the controller 100 controls the direct transfer arm A6 so as to transfer the wafer W of the shelf unit U10 to the shelf unit U11, and controls the delivery arm A8 so as to send the wafer W to the exposure apparatus 3. Thereafter, the controller 100 controls the delivery arm A8 so as to receive the wafer W on which an exposure processing has been performed from the exposure apparatus 3 and return the wafer W to the shelf unit U11.

Subsequently, the controller 100 controls the transfer arm A3 so as to transfer the wafer W of the shelf unit U11 to each unit in the processing module 17, and controls the liquid processing unit U1 and the thermal processing unit U2 so as to perform a developing processing on the resist film of the wafer W. Thereafter, the controller 100 controls the transfer arm A3 so as to return the wafer W to the shelf unit U10, and controls the elevating arm A7 and the delivery arm A1 so as to return the wafer W into the carrier 11. In this way, the coating and developing processing is completed.

Meanwhile, a specific configuration of the substrate processing apparatus is not limited to the configuration of the coating and developing apparatus 2 exemplified above. The substrate processing apparatus may be of any type provided with the liquid processing unit U1 for a developing processing (liquid processing unit U1 of the processing module 17) and the controller 100 capable of controlling the liquid processing unit U1.

[Hydrophobic Processing Unit]

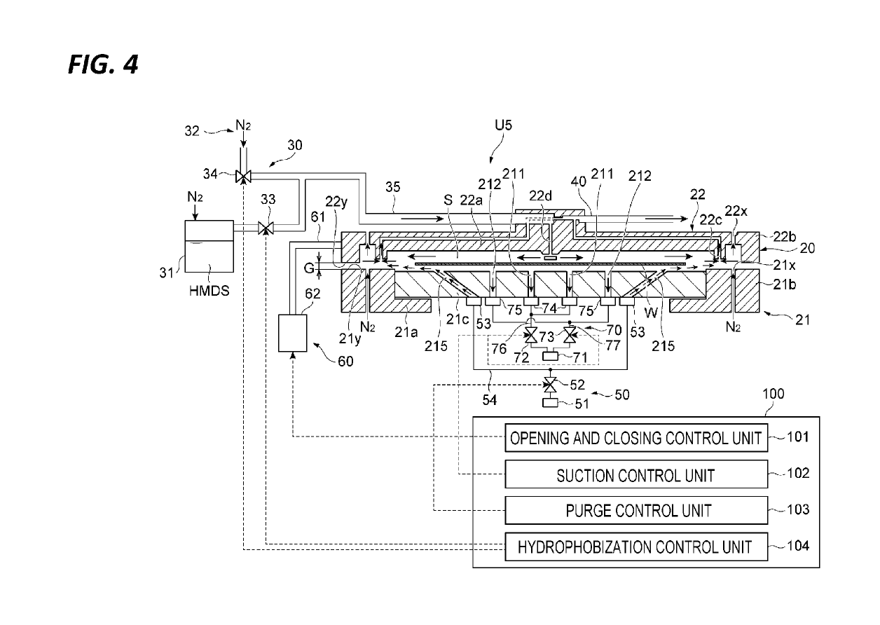

Next, the hydrophobic processing unit U5 of the processing module 14 will be described in detail. The hydrophobic processing unit U5 is a processing unit that performs a hydrophobic processing for enhancing adherence when coating various films on the surface of the wafer W on which the lower layer film has been formed, for example. As illustrated in FIG. 4, the hydrophobic processing unit U5 includes a hydrophobic processing device 20, a gas supply unit 30, an exhaust pipe 40, a rear surface purge gas supply unit 50 (fluid supply source), an opening and closing unit 60, a suction unit 70 (suction mechanism), and the controller 100 (control unit).

(Hydrophobic Processing Device)

The hydrophobic processing device 20 includes a processing container 21 and a lid 22. The processing container 21 is a container that accommodates therein the wafer W as a processing object. The processing container 21 includes a circular bottom plate 21a that is horizontally disposed, a peripheral wall 21b extending vertically upward from a peripheral edge portion of the bottom plate 21a, and a hot plate 21c (placing table). Meanwhile, the hydrophobic processing device 20 includes, for example, three support pins (not illustrated) that support the wafer W. The support pins are raised and lowered by an air cylinder (not illustrated), for example. Thus, the wafer W is raised and is placed at a desired position on the hot plate 21c. A through-hole 21x is formed in the peripheral wall 21b to penetrate the peripheral wall 21b in the thickness direction (in which the peripheral wall 21b extends).

The hot plate 21c is a disk-shaped member on which the wafer W as a processing object is placed such that the wafer W is heated (thermally processed). The hot plate 21c is placed on the bottom plate 21a and is accommodated in the processing container 21. The hot plate 21c incorporates therein, for example, a heating wire (not illustrated), and is raised in temperature when power is supplied to the heating wire. The temperature of the hot plate 21c ranges, for example, from 90° C. to 200° C.

The hot plate 21c is formed with first through-holes 211 and 212 (hole portion) and a second through-hole 215 (discharge portion) which penetrate the hot plate 21c in the thickness direction. The first through-holes 211 and 212 are formed in the vertical direction (the direction perpendicular to a placing surface of the hot plate 21c on which the wafer W is placed). For example, in a case where the diameter of the wafer W is about 300 mm and the diameter of the hot plate 21c is about 350 mm, the first through-holes 211 and 212 are formed at positions spaced apart from the center of the hot plate 21c in the radial direction by 40 mm to 120 mm A plurality of first through-holes 211 is formed at the innermost side (radially inward) among the above-described through-holes, and are arranged side by side in the circumferential direction at positions spaced apart from the center of the hot plate 21c in the radial direction by a predetermined distance. A plurality of first through-holes 212 is formed at positions radially outward of the first through-holes 211, and are arranged side by side in the circumferential direction at positions spaced apart from the center of the hot plate 21c in the radial direction by a predetermined distance. The second through-hole 215 extends radially (obliquely) from the rear surface side of the hot plate 21c (a side opposite to the placing surface on which the wafer W is placed) toward the placing surface side of the hot plate 21c so as to be directed radially outward from the center of the hot plate 21c. An inclination angle of the second through-hole 215 (an inclination angle with respect to the placing surface of the hot plate 21c on which the wafer W is placed) is, for example, 60 degrees or less. The inclination angle may be 30 degrees or less. A plurality of second through-holes 215 is formed at positions radially outward of the first through-holes 212, and is arranged side by side in the circumferential direction. The plurality of second through-holes 215 is formed in a concentric shape with respect to the wafer W. That is, the regions in which the plurality of second through-holes 215 is formed are provided in a concentric shape with respect to the wafer W. Meanwhile, the plurality of second through-holes 215 arranged in the circumferential direction may communicate with each other in the circumferential direction to form one slit as a whole.

The lid 22 is a lid member that is placed so as to cover an upper opening in the processing container 21. The lid 22 includes a circular top plate 22a that is horizontally disposed and a peripheral wall 22b extending vertically downward from a peripheral edge portion of the top plate 22a. Even in a state where the lid 22 is disposed at a position at which the lid 22 covers the opening in the processing container 21 by the opening and closing unit 60 to be described later, a predetermined gap G is formed between a lower end 22y of the lid 22 in a peripheral edge portion of the peripheral wall 22b and an upper end 21y of the processing container 21 in a peripheral edge portion of the peripheral wall 21b. The predetermined gap G is set to, for example, a range from about 0.1 mm to about 2.0 mm. In a state where the predetermined gap G is formed, a processing space S is formed between the processing container 21 and the lid 22. The peripheral wall 22b is formed with a through-hole 22x which penetrates the peripheral wall 22b in the thickness direction (in which the peripheral wall 22b extends) and also formed with an outer peripheral exhaust portion 22c. In addition, a gas flow path 22d is formed in the center portion of the top plate 22a.

The through-hole 22x is formed so as to communicate with the through-hole 21x in the processing container 21 in a state where the lid 22 is disposed at the position at which the lid 22 covers the opening in the processing container 21. Nitrogen gas as a purge gas is supplied from the lower end side of the through-hole 21x when hexamethyldisilazane (HMDS) gas is supplied to the inside of the processing container 21 by the gas supply unit 30 to be described later. In this case, excess nitrogen gas in a purge processing flows from the through-hole 21x to the through-hole 22x and is discharged from an upper end of the through-hole 22x to the outside of the processing container 21. Therefore, a so-called air curtain is formed between the inside and the outside of the processing container 21, and the leakage of HMDS gas to the outside of the processing container 21 is prevented. The air curtain has a function of preventing the HMDS gas in the processing container 21 from reacting with moisture in the external atmosphere.

The outer peripheral exhaust portion 22c exhausts the gas in the processing space S from the outer side (outer peripheral side) of the wafer W placed on the hot plate 21c. The outer peripheral exhaust portion 22c is formed radially inward of the through-hole 22x in the peripheral wall 22b, and is constituted by, for example, a plurality of exhaust holes annularly and equidistantly arranged in the circumferential direction. Each exhaust hole communicates with the exhaust pipe 40 to be described later.

The gas flow path 22d is formed in the center portion of the top plate 22a, and causes HMDS gas as a processing gas and nitrogen gas as a purge gas supplied from the gas supply unit 30 to flow into the processing space S. The gas flow path 22d is formed so as to penetrate the top plate 22a in the thickness direction and communicates with a gas supply pipe 35 of the gas supply unit 30.

(Gas Supply Unit)

The gas supply unit 30 supplies HMDS gas as a processing gas for making the surface of the wafer W hydrophobic to the processing container 21. The gas concentration (Vol %) of HMDS gas is, for example, 1%. The gas supply unit 30 supplies the HMDS gas as a processing gas under the control of the controller 100 (details of which will be described later).

In addition, the gas supply unit 30 also functions as a purge gas supply unit that supplies nitrogen gas as a purge gas in order to purge the HMDS gas in the processing container 21. The relative humidity of nitrogen gas is 0% or a value close to 0% as much as possible, and is extremely low compared with the air and the HMDS gas described above. The gas supply unit 30 supplies the nitrogen gas as a purge gas after supplying the HMDS gas as a processing gas under the control of the controller 100 (details of which will be described later).

The gas supply unit 30 includes an HMDS supply source 31, a nitrogen gas supply source 32, an HMDS supply valve 33, an N₂ purge valve 34, and the gas supply pipe 35. The HMDS supply source 31 is a supply source of HMDS gas as a processing gas. The HMDS supply source 31 stores therein, for example, an HMDS liquid and performs nitrogen bubbling on the liquid. Thus, HMDS is vaporized to be HMDS gas. Although a processing gas supplied from the HMDS supply source 31 contains not only HMDS gas but also a minute amount of nitrogen gas in order to perform nitrogen bubbling, in the present embodiment, a processing gas supplied from the HMDS supply source 31 is simply described as HMDS gas. The nitrogen gas supply source 32 is a supply source of nitrogen gas as a purge gas. The gas supply pipe 35 is a pipe that interconnects the HMDS supply source 31 and the gas flow path 22d and interconnects the nitrogen gas supply source 32 and the gas flow path 22d.

The HMDS supply valve 33 is provided on the gas supply pipe 35 which interconnects the HMDS supply source 31 and the gas flow path 22d. The N₂ purge valve 34 is provided on the gas supply pipe 35 which interconnects the nitrogen gas supply source 32 and the gas flow path 22d. The HMDS supply valve 33 and the N₂ purge valve 34 open and close a flow path in the gas supply pipe 35. When the HMDS supply valve 33 is opened, a processing gas (HMDS gas) flows from the HMDS supply source 31 to the gas flow path 22d through the gas supply pipe 35. When the N₂ purge valve 34 is opened, a purge gas (nitrogen gas) flows from the nitrogen gas supply source 32 to the gas flow path 22d through the gas supply pipe 35. The opening and closing of the HMDS supply valve 33 and the N₂ purge valve 34 is controlled by the controller 100 (details of which will be described later).

(Exhaust Pipe)

The exhaust pipe 40 is a pipe that discharges the gas inside the processing container 21 to the outside. The exhaust pipe 40 communicates with each exhaust hole of the outer peripheral exhaust portion 22c. The air, processing gas (HMDS gas), and nitrogen gas as a purge gas may flow to the exhaust pipe 40 through the outer peripheral exhaust portion 22c.

(Opening and Closing Unit)

The opening and closing unit 60 opens the processing container 21 under the control of the controller 100 (details of which will be described later) to allow the transfer arm A3 to carry the wafer W into the processing container 21. The opening and closing unit 60 includes a gripping unit 61 that grips the lid 22 and a drive unit 62 that includes an actuator and drives the gripping unit 61. The drive unit 62 raises and lowers the lid 22 relative to the processing container 21 by driving the gripping unit 61 under the control of the controller 100. The opening and closing unit 60 opens the processing container 21 by moving the lid 22 upward from a state (closed state) where the lid 22 is disposed at the position at which the lid 22 covers the opening in the processing container 21. The opening and closing unit 60 covers the opening in the processing container 21 with the lid 22 by moving the lid 22 downward from a state (opened state) where the processing container 21 is opened.

(Rear Surface Purge Gas Supply Unit)

The rear surface purge gas supply unit 50 discharges a fluid to the second through-hole 215 and forms a horizontal airflow toward the outer side (radially outward) of the wafer W on the rear surface side of the wafer W under to the control of the controller 100 (details of which will be described later). The discharge flow rate of the rear surface purge gas supply unit 50 is higher than the suction flow rate of the suction unit 70 to be described later. While the fluid is supplied to the rear surface side of the wafer W by the rear surface purge gas supply unit 50, HMDS gas as a processing gas is supplied to the surface side of the wafer W by the above-described gas supply unit 30. Here, the flow velocity of the HMDS gas supplied by the gas supply unit 30 toward the outside of the surface of the wafer W is lower than the flow velocity of the airflow formed by the rear surface purge gas supply unit 50 toward the outside of the rear surface of the wafer W.

The rear surface purge gas supply unit 50 includes a nitrogen gas supply source 51, an N₂ purge valve 52, a supply port 53, and a gas supply pipe 54. The nitrogen gas supply source 51 is a supply source of nitrogen gas as a purge gas. The supply port 53 is a supply port that is formed in an end of the second through-hole 215 (the end on the rear surface side of the hot plate 21c) and introduces nitrogen gas into the second through-hole 215. The gas supply pipe 54 is a pipe that interconnects the nitrogen gas supply source 51 and the supply port 53. The N₂ purge valve 52 is provided on the gas supply pipe 54, and opens and closes a flow path in the gas supply pipe 54. When the N₂ purge valve 52 is opened, a purge gas (nitrogen gas) flows from the nitrogen gas supply source 51 to the second through-hole 215 through the gas supply pipe 54 and the supply port 53. The opening and closing of the N₂ purge valve 52 are controlled by the controller 100 (details of which will be described later).

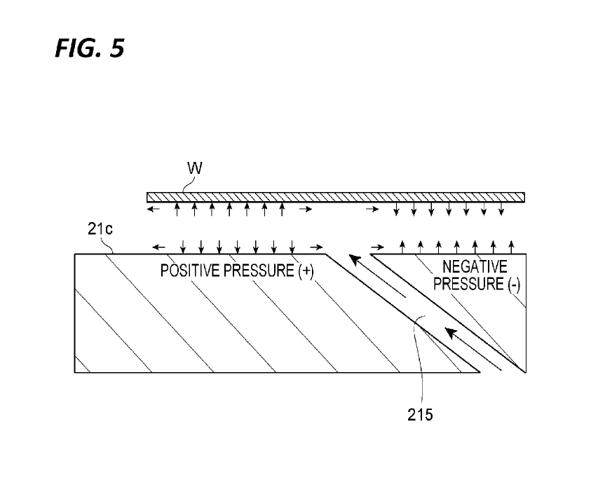

As described above, the second through-hole 215 extends not vertically but obliquely with respect to the placing surface of the hot plate 21c on which the wafer W is placed (and also in the radially outward direction from the rear surface side of the hot plate 21c toward the placing surface side on which the wafer W is placed). A purge gas discharged to the second through-hole 215 forms a horizontal airflow toward the outside (radially outward) of the wafer W on the rear surface side of the wafer W. Through the formation of such an airflow, as illustrated in FIG. 5, by the Bernoulli effect, a negative pressure is generated in the region close to the radial center of the rear surface of the wafer W (the region closer to the center than the region corresponding to a discharge port of the second through-hole 215), and a force is applied to suck the wafer W toward the hot plate 21c. In addition, a positive pressure is generated in a radial outer region of the rear surface of the wafer W (the region outward of the region corresponding to the discharge port of the second through-hole 215), and a force is applied in a direction to float the wafer W

(Suction Unit)

The suction unit 70 applies a suction force to the rear surface of the wafer W through the first through-holes 211 and 212 to hold the wafer W (specifically, hold the wafer W on the hot plate 21c).

The suction unit 70 includes a suction device 71, suction valves 72 and 73, suction ports 74 and 75, and suction pipes 76 and 77. The suction device 71 is a mechanism that sucks up a gas by the action of a pressure. The suction port 74 is formed in an end of the first through-hole 211 (the end on the rear surface side of the hot plate 21c), and delivers a suction force applied by the suction device 71 to a gas in the processing container 21 through the first through-hole 211. The suction port 75 is formed in an end of the first through-hole 212 (the end on the rear surface side of the hot plate 21c), and delivers a suction force applied by the suction device 71 to a gas in the processing container 21 through the first through-hole 212. The suction pipe 76 is a pipe that interconnects the suction device 71 and the suction port 74. The suction pipe 77 is a pipe that interconnects the suction device 71 and the suction port 75. The suction valve 72 is provided on the suction pipe 76, and opens and closes a flow path in the suction pipe 76. When the suction valve 72 is opened, the gas in the processing container 21 is sucked up to the suction pipe 76 side through the first through-hole 211. The suction valve 73 is provided on the suction pipe 77, and opens and closes a flow path in the suction pipe 77. When the suction valve 73 is opened, the gas in the processing container 21 is sucked up to the suction pipe 77 side through the first through-hole 212. The opening and closing of the suction valves 72 and 73 is controlled by the controller 100 (details of which will be described later).

(Controller)

The controller 100 is configured to control the suction unit 70 to start suction, and control the rear surface purge gas supply unit 50 to start the discharge of a fluid (nitrogen gas) after the suction by the suction unit 70 is started.

In addition, the controller 100 is configured to further control the gas supply unit 30 to start supply of HMDS gas as a processing gas after the discharge of the fluid (nitrogen gas) by the rear surface purge gas supply unit 50 is started.

As illustrated in FIG. 4, the controller 100 includes an opening and closing control unit 101, a suction control unit 102, a purge control unit 103, and a hydrophobization control unit 104 as functional modules.

The opening and closing control unit 101 controls the opening and closing unit 60 so as to open the processing container 21. Specifically, the opening and closing control unit 101 controls the drive unit 62 of the opening and closing unit 60 such that the lid 22 covering the opening in the processing container 21 is moved upward (away from the processing container 21) (such that the lid 22 is opened). When the lid 22 is opened, the processing container 21 is opened, and air is supplied into the processing container 21. After the lid 22 is opened, the opening and closing control unit 101 controls the opening and closing unit 60 such that the opening in the processing container 21 is covered with the lid 22 after the carry-in of the wafer W into the processing container 21 and the placement of the wafer W on the hot plate 21c are completed. Specifically, the opening and closing control unit 101 controls the drive unit 62 of the opening and closing unit 60 such that the lid 22 is moved downward (toward the processing container 21) from a state where the lid 22 opens the processing container 21 (such that the lid 22 is closed). When the lid 22 is closed, the inflow of air from the opening in the processing container 21 terminates. Meanwhile, as described above, even in a state where the lid 22 is closed, a minute amount of air is supplied to the processing container 21 through the gap G between the lid 22 and the processing container 21.

The suction control unit 102 controls the suction unit 70 such that a suction force is applied to the rear surface of the wafer W. Specifically, after the wafer W is placed on the hot plate 21c and the lid 22 is closed by the opening and closing control unit 101, the suction control unit 102 opens the suction valve 72 such that the suction force by the suction unit 71 acts on the first through-hole 211 and a gas in the processing container 21. In addition, after the wafer W is placed on the hot plate 21c and the lid 22 is closed by the opening and closing control unit 101, the suction control unit 102 opens the suction valve 73 such that the suction force by the suction unit 71 acts on the first through-hole 212 and the gas in the processing container 21. The suction control unit 102 opens the suction valves 72 and 73 such that the suction force is continuously applied to the rear surface of the wafer W until a substrate processing (hydrophobic processing) on the wafer W placed on the hot plate 21c is completed. The suction control unit 102 closes the suction valves 72 and 73 when the substrate processing (hydrophobic processing) on the wafer W is completed. Meanwhile, the suction control unit 102 may appropriately change the suction force by the suction unit 70 during suction. For example, the suction control unit 102 may perform control so as to allow the wafer W to be sucked with a strong suction force at the initial stage of a suction processing and to gradually weaken the suction force.

The purge control unit 103 controls the rear surface purge gas supply unit 50 such that nitrogen gas is supplied to the second through-hole 215. Specifically, the purge control unit 103 opens the N₂ purge valve 52 such that the discharge of a fluid (nitrogen gas) into the second through-hole 215 is started after the suction by the suction unit 70 is started. The purge control unit 103 opens the N₂ purge valve 52 such that the fluid is continuously discharged to the second through-hole 215 until a substrate processing (hydrophobic processing) on the wafer W placed on the hot plate 21c is completed. The purge control unit 103 closes the N₂ purge valve 52 when the substrate processing (hydrophobic processing) on the wafer W is completed.

The hydrophobization control unit 104 controls the gas supply unit 30 such that HMDS gas is supplied. Specifically, the hydrophobization control unit 104 opens the HMDS supply valve 33 after the discharge of nitrogen gas by the rear surface purge gas supply unit 50 is started. Therefore, HMDS gas is supplied from the HMDS supply source 31 into the processing container 21 through the gas supply pipe 35 and the gas flow path 22d. After a predetermined time (e.g., 30 seconds) passes, the hydrophobization control unit 104 closes the HMDS supply valve 33 to terminate the supply of the HMDS gas.

The hydrophobization control unit 104 controls the gas supply unit 30 so as to supply nitrogen gas as a purge gas after the supply of the HMDS gas by the gas supply unit 30 terminates. Specifically, the hydrophobization control unit 104 opens the N₂ purge valve 34 after the supply of the HMDS gas described above terminates. Therefore, nitrogen gas is supplied from the nitrogen gas supply source 32 into the processing container 21 through the gas supply pipe 35 and the gas flow path 22d. After a predetermined time (e.g., 10 seconds) passes, the hydrophobization control unit 104 closes the N₂ purge valve 34 to terminate the supply of the nitrogen gas as a purge gas.

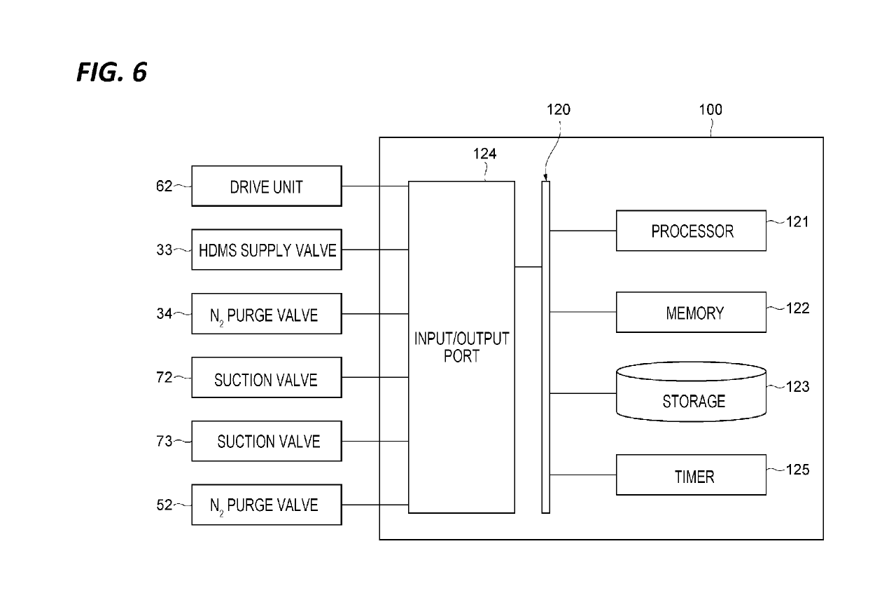

The controller 100 is constituted by one or a plurality of control computers. For example, the controller 100 includes a circuit 120 illustrated in FIG. 6. The circuit 120 includes one or a plurality of processors 121, a memory 122, a storage 123, an input/output port 124, and a timer 125.

The input/output port 124 performs the input and output of electric signals between the drive unit 62 of the opening and closing unit 60, the HMDS supply valve 33 of the gas supply unit 30, the N₂ purge valve 34 of the gas supply unit 30, the suction valves 72 and 73 of the suction unit 70, and the N₂ purge valve 52 of the rear surface purge gas supply unit 50, for example. The timer 125 measures an elapsed time, for example, by counting a reference pulse of a constant period. The storage 123 includes a computer readable recording medium such as, for example, a hard disk. The recording medium records therein a program for executing a substrate processing procedure to be described later. The recording medium may be a removable medium such as, for example, a nonvolatile semiconductor memory, a magnetic disk, or an optical disk. The memory 122 temporarily records the program loaded from the recording medium of the storage 123 and the calculation result by the processor 121. The processor 121 cooperates with the memory 122 to execute the program, thereby constituting each of the above-described functional modules.

Meanwhile, a hardware configuration of the controller 100 may not be necessarily limited to a configuration of each functional module by a program. For example, each functional module of the controller 100 may be constituted by a dedicated logic circuit or an application specific integrated circuit (ASIC) in which the logic circuit is integrated.

[Hydrophobic Processing Procedure]

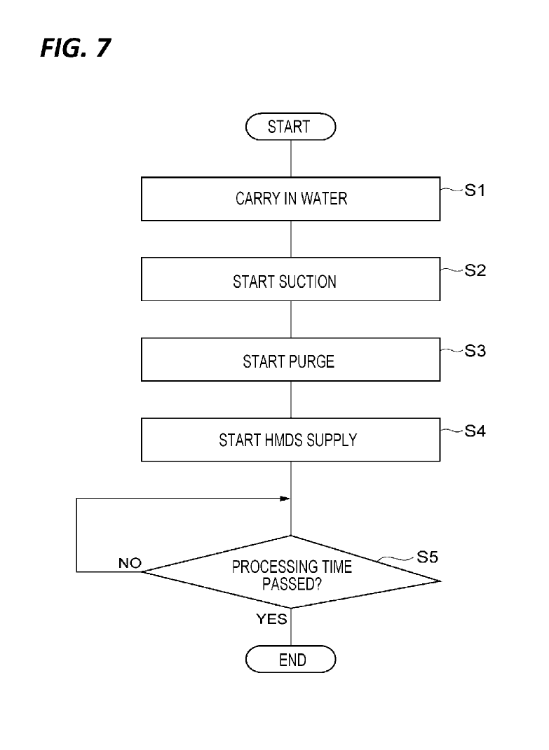

Next, as an example of a substrate processing method, a hydrophobic processing procedure executed by the hydrophobic processing unit U5 under the control of the controller 100 will be described with reference to FIG. 7.

First, the controller 100 controls the drive unit 62 of the opening and closing unit 60 such that the lid 22 covering the opening in the processing container 21 is moved upward (such that the lid 22 is opened) to perform the carry-in of the wafer W (step S1).

Subsequently, the controller 100 controls the suction unit 70 such that suction of the rear surface of the wafer W is started (step S2). Specifically, after the wafer W is placed on the hot plate 21c and the lid 22 is closed, the controller 100 opens the suction valve 72 such that a suction force by the suction unit 71 acts on the first through-hole 211 and a gas in the processing container 21. In addition, after the wafer W is placed on the hot plate 21c and the lid 22 is closed, the controller 100 opens the suction valve 73 such that the suction force by the suction unit 71 acts on the first through-hole 212 and the gas in the processing container 21.

Subsequently, the controller 100 controls the rear surface purge gas supply unit 50 such that the supply (purge) of nitrogen gas to the second through-hole 215 is started (step S3). Specifically, the controller 100 opens the N₂ purge valve 52 such that the discharge of a fluid (nitrogen gas) to the second through-hole 215 is started after the suction by the suction unit 70 is started.

Subsequently, the controller 100 controls the gas supply unit 30 such that the supply of HMDS gas is started (step S4). Specifically, the controller 100 opens the HMDS supply valve 33 after the discharge of the nitrogen gas by the rear surface purge gas supply unit 50 is started. After a predetermined time (e.g., 30 seconds) passes, the controller 100 closes the HMDS supply valve 33 to terminate the supply of the HMDS gas, and controls the gas supply unit 30 so as to supply nitrogen gas as a purge gas.

Subsequently, the controller 100 determines whether or not a predetermined processing time has passed after the processing of step S4 is started (step S5). The determination of step S5 is repeated until it is determined in step S5 that the predetermined processing time has passed. On the other hand, when it is determined in step S5 that the predetermined processing time has passed, the hydrophobic processing terminates.

### Effects of the Present Embodiment

The hydrophobic processing unit U5 according to the present embodiment includes the hot plate 21c on which the wafer W as a processing object is placed, the suction unit 70 which applies a suction force to the rear surface of the wafer W through the plurality of first through-holes 211 and 212 formed in the hot plate 21c to hold the wafer W, and the rear surface purge gas supply unit 50 which discharges a fluid to the plurality of second through-holes 215 formed in the hot plate 21c outward of the first through-holes 211 and 212 in the hot plate 21c and forms a horizontal airflow toward the outside of the wafer W on the rear surface side of the wafer W.

In the hydrophobic processing unit U5 according to the present embodiment, the rear surface purge gas supply unit 50 discharges the fluid to the second through-hole 215 formed outward of the first through-holes 211 and 212 and forms the horizontal airflow toward the outside of the wafer W. Through the formation of the airflow, by the Bernoulli effect, a negative pressure is generated in the region close to the center of the rear surface of the wafer W (the region closer to the center than the region corresponding to the discharge port of the second through-hole 215), and a force is applied to suck the wafer W toward the hot plate 21c (see FIG. 5). Both the suction force by the negative pressure caused by the Bernoulli effect and the suction force of the suction unit 70 are applied to the wafer W. Thus, it is possible to appropriately hold the wafer W on the hot plate 21c and it is possible to prevent the warpage of the wafer W. For example, when a warped wafer is treated with HMDS gas, the temperature of the wafer W at the outer peripheral portion or the center portion of the wafer W is relatively lower than that at the remaining portion, and as a result, the reaction between HMDS gas and the wafer W does not proceed and the contact angle decreases. In this respect, it is possible to prevent the occurrence of the problems by preventing the warpage of the wafer W by the above-described method.

In addition, by the Bernoulli effect caused by the horizontal airflow, a positive pressure is generated in an outer region of the rear surface of the wafer W (the region outward of the region corresponding to the discharge port of the second through-hole 215) (see FIG. 5). In this way, since a force is also applied to a direction different from the suction force of the suction unit 70 by the rear surface purge gas supply unit 50, by adjusting the discharge flow rate of the fluid in the rear surface purge gas supply unit 50 in consideration of the suction force of the suction unit 70, it is possible to adjust the posture of the wafer W on the hot plate 21c (e.g., hold the wafer W in a state where the wafer W and the hot plate 21c are spaced apart from each other by a constant distance) and to increase the degree of freedom of a substrate processing. In addition, since the positive pressure of the Bernoulli effect makes it difficult for a gap pin (not illustrated) on the hot plate 21c to come into contact with the wafer W, it is possible to appropriately prevent, for example, the occurrence of scratches on the rear surface of the wafer W and the generation of particles caused when a metal film of the wafer W peels off.

The second through-hole 215 is formed in a plural number, and a plurality of second through-holes 215 is formed in a concentric shape with respect to the wafer W. Therefore, the regions on the rear surface side of the wafer W corresponding to the plurality of second through-holes 215 in which the airflow is formed may be at the same position (having the same distance from the center of the wafer W), and the wafer W may be held more stably.

The second through-hole 215 may extend obliquely with respect to the placing surface of the hot plate 21c on which the wafer W is placed. Specifically, an inclination angle of the second through-hole 215 with respect to the placing surface is 60 degrees or less. The inclination angle may be 30 degrees or less. Therefore, a horizontal airflow may be easily formed on the rear surface side of the wafer W.

The hydrophobic processing unit U5 includes the gas supply unit 30 which supplies HMDS gas as a processing gas to the processing container 21 which accommodates therein the wafer W, and the hot plate 21c is a hot plate that heats the wafer W. In a configuration in which the wafer W is heated by the hot plate 21c and the processing gas is supplied to the wafer W as described above, the processing gas may circulate to the rear surface side of the wafer W and react with the wafer W. Specifically, it is conceivable that a residue (foreign substance) increases at the time of back rinse due to the reaction between the HMDS gas and the rear surface of the wafer W and that the foreign substance accumulates on a stage of an exposure machine. In this respect, in the hydrophobic processing unit U5, since a fluid is discharged toward the outside of the wafer W from the second through-hole 215 outward of the first through-holes 211 and 212, it is possible to prevent the processing gas from circulating to the rear surface side of the wafer W by the fluid.

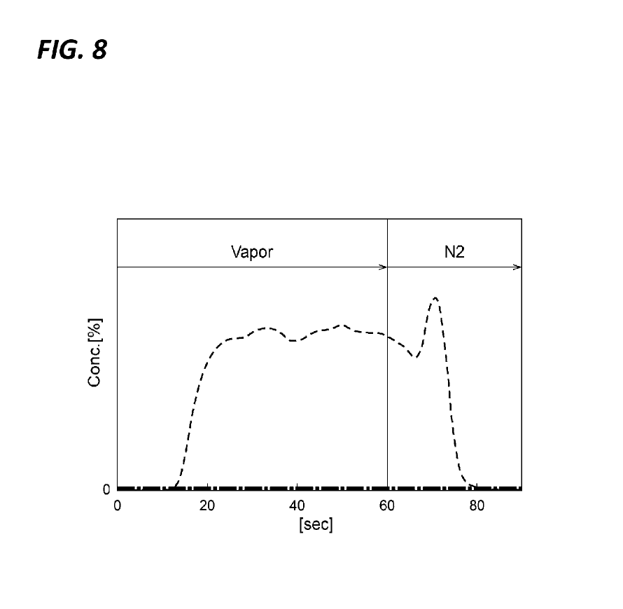

FIG. 8 is a diagram illustrating that a processing gas is prevented from circulating to the rear surface side of the wafer W by a fluid discharged from the rear surface purge gas supply unit 50 described above. In FIG. 8, the horizontal axis represents time and the vertical axis represents the concentration of a processing gas (HMDS gas). In FIG. 8, “Vapor” indicates a time zone during which HMDS gas is supplied from the gas supply unit 30 and “N2” indicates a time zone during which purge nitrogen gas is supplied from the gas supply unit 30. In FIG. 8, the broken line illustrates the concentration of HMDS gas on the rear surface of the wafer W when no fluid is discharged from the rear surface purge gas supply unit 50, and the one-dot dashed line illustrates the concentration of HMDS gas on the rear surface of the wafer W when a fluid is discharged from the rear surface purge gas supply unit 50 (e.g., at 5 L/min). As illustrated in FIG. 8, when a fluid is discharged from the rear surface purge gas supply unit 50, the concentration of HMDS gas on the rear surface of the wafer W is close to zero. In this respect, it can be understood that a processing gas may be prevented from circulating to the rear surface side of the wafer W when a fluid is discharged from the rear surface purge gas supply unit 50. Meanwhile, as the amount of purge from the rear surface purge gas supply unit 50 increases, it is possible to effectively prevent HMDS gas from circulating to the rear surface side of the wafer W.

The flow velocity of HMDS gas supplied by the gas supply unit 30 toward the outside of the surface of the wafer W may be lower than the flow velocity of an airflow formed by the rear surface purge gas supply unit 50 toward the outside of the rear surface of the wafer W. Therefore, it is possible to appropriately hold the wafer W on the hot plate 21c by the Bernoulli effect.

The discharge flow rate of the rear surface purge gas supply unit 50 is higher than the suction flow rate of the suction unit 70. It is conceivable that the above-described processing gas is guided to the rear surface side of the wafer W by the suction of the suction unit 70. In this respect, by setting the discharge flow rate of the fluid discharged toward the outside of the wafer W to be higher than the suction flow rate of the suction unit 70, it is possible to effectively prevent the processing gas from circulating to the rear surface side of the wafer W by the suction of the suction unit 70.

The hydrophobic processing unit U5 includes the controller 100 configured to control the suction unit 70 to start suction, and control the rear surface purge gas supply unit 50 to start discharge of a fluid after the suction by the suction unit 70 is started. For example, when the discharge of the fluid by the rear surface purge gas supply unit 50 is performed prior to the suction by the suction unit 70, it is conceivable that the wafer W excessively floats due to the positive pressure of the Bernoulli effect and the warpage of the wafer W may not be sufficiently prevented. In this respect, when the discharge of the fluid by the rear surface purge gas supply unit 50 is started to generate the positive pressure after the wafer W is held toward the hot plate 21c by the suction unit 70, it is possible to adjust the amount of floating of the wafer W by adjusting the positive pressure of the Bernoulli effect after the wafer W is reliably held on the hot plate 21c (i.e., after the warpage of the wafer W is appropriately prevented).

The controller 100 controls the gas supply unit 30 such that the supply of a processing gas is started after the discharge of the fluid by the rear surface purge gas supply unit 50 is started. Therefore, it is possible to more effectively prevent the processing gas from circulating to the rear surface of the wafer W.

Although the embodiment has been described above, the present disclosure is not limited to the above embodiment. For example, an example in which a configuration including the rear surface purge gas supply unit 50, for example, is applied to the hydrophobic processing unit U5 has been described, but the present disclosure is not limited thereto. That is, the configuration including the rear surface purge gas supply unit 50, for example, may also be applied to other apparatuses having a possibility of the processing gas circulating to the rear surface of the wafer W such as, for example, a chemical vapor deposition (CVD) apparatus and a dry etching apparatus. In addition, the configuration including the rear surface purge gas supply unit 50, for example, may also be applied to any other apparatus having a possibility of, for example, an unnecessary substance generated during a processing circulating to the rear surface of the wafer W such as, for example, a thermal processing (post apply bake (PAB)) apparatus. In such an apparatus, a solvent in a coating film is volatilized by heating the wafer W coated with a resist, BARC, or SPIN On Carbon (SOC). In this case, the rear surface purge gas supply unit 50 prevents a sublimate (unnecessary substance) discharged from the film by a heating processing from circulating to the rear surface of the wafer W. In addition, the configuration including the rear surface purge gas supply unit 50, for example, may also be applied to an apparatus that does not cause, for example, a processing gas to circulate to the rear surface side of the wafer W, for example, a post exposure bake (PEB) apparatus. Even in this case, for example, the rear surface purge gas supply unit 50 may prevent, for example, the warpage of the wafer W and the generation of particles on the rear surface. In addition, the configuration including the rear surface purge gas supply unit 50, for example, may also be applied to an apparatus having a rotation mechanism on a placing table (e.g., a developing apparatus of the wafer W).

In addition, the second through-hole 215 has been described above as extending radially (obliquely) from the rear surface side of the hot plate 21c (the side opposite to the placing surface on which the wafer W is placed) toward the placing surface side of the hot plate 21c so as to be directed radially outward from the center of the hot plate 21c, but is not limited thereto. That is, the second through-hole 215 may have any other configuration as long as a horizontal airflow is formed toward the outside of the wafer W by a fluid flowing through the second through-hole 215. For example, the second through-hole 215 may vertically extend upward from the rear surface side of the hot plate 21c and rapidly bend in the horizontal direction at the placing surface side of the hot plate 21c.

The hot plate 21c has been described as having the first through-holes 211 and 212 as a hole portion and the second through-hole 215 as a discharge portion which penetrate the hot plate 21c in the thickness direction, but is limited thereto, and the hole portion and the discharge portion may not penetrate the hot plate 21c.

According to the present disclosure, it is possible to perform a substrate processing in a state where the warpage of a substrate is prevented.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a placing table on which a substrate to be processed is placed;
a suction mechanism including a pipe configured to apply a suction force to a rear surface of the substrate through one or a plurality of hole portions formed in the placing table to hold the substrate; and
a fluid supply source configured to discharge a fluid to one or a plurality of discharge portions formed in the placing table outward of the hole portions in the placing table and to form a horizontal airflow toward an outside of the substrate on a rear surface of the substrate.

2. The substrate processing apparatus of claim 1, wherein a plurality of discharge portions is provided, and
the plurality of discharge portions is formed in a concentric shape with respect to the substrate.

3. The substrate processing apparatus of claim 1, wherein the discharge portions extend obliquely with respect to a placing surface of the placing table on which the substrate is placed.

4. The substrate processing apparatus of claim 3, wherein an inclination angle of the discharge portions with respect to the placing surface is 60 degrees or less or 30 degrees or less.

5. The substrate processing apparatus of claim 1, further comprising:
a processing gas supply source configured to supply a processing gas to a processing container that accommodates the substrate,
wherein the placing table is a hot plate configured to heat the substrate.

6. The substrate processing apparatus of claim 5, wherein a flow velocity of the processing gas supplied by the processing gas supply source toward an outside of a surface of the substrate is lower than a flow velocity of the airflow formed by the fluid supply source toward an outside of the rear surface of the substrate.

7. The substrate processing apparatus of claim 5, wherein a discharge flow rate of the fluid supply source is higher than a suction flow rate of the suction mechanism.

8. The substrate processing apparatus of claim 5, further comprising:
a controller configured to control the suction mechanism to start suction, and control the fluid supply source to start discharge of the fluid after the suction by the suction mechanism is started.

9. The substrate processing apparatus of claim 8, wherein the controller is further configured to control the processing gas supply source to start supply of the processing gas after the discharge of the fluid by the fluid supply source is started.

10. The substrate processing apparatus of claim 2, wherein the discharge portions extend obliquely with respect to a placing surface of the placing table on which the substrate is placed.

11. The substrate processing apparatus of claim 10, wherein an inclination angle of the discharge portions with respect to the placing surface is 60 degrees or less or 30 degrees or less.

12. The substrate processing apparatus of claim 11, further comprising:
a processing gas supply source configured to supply a processing gas to a processing container that accommodates the substrate,
wherein the placing table is a hot plate configured to heat the substrate.

13. The substrate processing apparatus of claim 12, wherein a flow velocity of the processing gas supplied by the processing gas supply source toward an outside of a surface of the substrate is lower than a flow velocity of the airflow formed by the fluid supply source toward an outside of the rear surface of the substrate.

14. The substrate processing apparatus of claim 13, wherein a discharge flow rate of the fluid supply source is higher than a suction flow rate of the suction mechanism.

15. The substrate processing apparatus of claim 14, further comprising:
a controller configured to control the suction mechanism to start suction, and control the airflow formation mechanism to start discharge of the fluid after suction by the suction mechanism is started.

16. The substrate processing apparatus of claim 15, wherein the controller is further configured to control the processing gas supply source to start supply of the processing gas after the discharge of the fluid by the fluid supply source is started.
